(19) United States
(12) Patent Application Publication
(10) Pub. No.: US 2025/0267995 A1
(43) Pub. Date: Aug. 21, 2025

(54) INTEGRATION OF AN LED ARRAY INTO A TRANSPARENT OPTICAL ELEMENT

(71) Applicant: Lumileds LLC, San Jose, CA (US)

(72) Inventors: Grigoriy BASIN, San Francisco, CA (US); Michael HOLUB, San Jose, CA (US); Brendan Jude MORAN, San Jose, CA (US)

(73) Assignee: Lumileds LLC, San Jose, CA (US)

(21) Appl. No.: 18/442,267

(22) Filed: Feb. 15, 2024

(51) Int. Cl. H01L 33/62; G02B 27/01; H01L 25/075; H01L 33/00; H01L 33/32

(52) U.S. Cl. CPC H10H 20/857; G02B 27/0172; H01L 25/0753; H10H 20/0133; H10H 20/825; G02B 2027/0178; H10H 20/0364

(57) ABSTRACT

A light-emitting apparatus includes: a transparent substrate; electrically conductive traces, bond pads, or land pads on the substrate; LEDs; and transparent molded material. The traces, bond pads, and land pads can be transparent, or can be sufficiently small and sufficiently sparse, to enable visual observation of a scene through the substrate and the traces, bond pads, or land pads. The LEDs are connected to the bond pads, and are sufficiently small and sparse so as to enable visual observation of the scene through them. The molded material can be a thermoplastic material or a thermoset material and is molded directly onto the substrate surface, without any intervening adhesive, and encapsulates the LEDs and the traces, bond pads, or land pads. Molten material or liquid precursors are injected into a mold enclosing the substrate with the LEDs and the traces, bond pads, or land pads.

### FIELD OF THE INVENTION

The field of the present invention relates to light-emitting apparatus and methods of making the same.

### BACKGROUND

Extended reality (XR) refers to environments generated by wearable computers and encompasses augmented reality (AR), virtual reality (VR), and mixed reality (MR) systems. An optical head-mounted display (OHMD) is one such wearable device that can project images into the user's field of view. The OHMD may incorporate an eye tracking system to detect the direction of the user's gaze and, in response, alter the optical projection to create a more immersive experience. One technique for tracking eye movement relies on analysis of infrared (IR) light that is directed toward the user's eye, scattered or reflected from the user's eye, and detected by one or more optical detectors, e.g., captured by an image sensor as spots of localized intensity know as glints. The accuracy of the eye tracking system can be improved by positioning multiple infrared LED light sources around the eye to produce a corresponding number of glints.

Conventional infrared LED packages can be several square millimeters in size and need to be placed in the peripheral frame of the OHMD for purposes of connecting to an electrical circuit that can power the LED as well as to avoid obstructing the user's field of view. Such an arrangement can result in suboptimal LED placement for glint-based eye tracking, can require higher output powers to compensate the indirect illumination of the user's eye, and can restrict the range of glint patterns that can be achieved. An alternative arrangement includes an array of LEDs integrated onto the OHMD eyepiece itself (e.g., visor, goggles, glasses, or other eyewear) so as to illuminate directly the user's eye (e.g., as in U.S. Pub. No. 2023/0393388 or U.S. application Ser. No. 17/985,897, each of which is incorporated by reference in its entirety). Direct illumination enables the use of smaller LEDs (e.g., miniature LEDs (mini-LEDs), or micro-LEDs with transverse dimensions less than 200 microns) operated at lower current while still achieving the necessary level of corneal irradiance, reducing overall system power consumption. An array of mini- or micro-LEDs can be attached to an optically transparent backplane and electrically connected with narrow metal or transparent conductive oxide traces; such an array can appear nearly invisible to the user. Instead of, or in addition to, infrared LEDs for eye-tracking, the array can include visible LEDs for, e.g., displaying alphanumeric, symbolic, or graphic information to the user. Such displayed information can be overlaid onto a real or virtual scene observed by the user.

### SUMMARY

An inventive light-emitting apparatus comprises: a transparent substrate; electrically conductive traces, bond pads, or land pads on the substrate surface; a set of LEDs; and a transparent molded material. The traces, bond pads, or land pads are formed by patterning an electrically conductive layer on the substrate surface. The electrically conductive layer can be transparent, or the traces, bond pads, or land pads can be sufficiently small and sufficiently sparse, to enable visual observation of a scene through the substrate along a sightline that passes through the traces, bond pads, or land pads. The LEDs are attached and electrically connected to the bond pads, and are sufficiently small and sparse so as to enable visual observation of the scene along the sightline. The molded material is molded directly onto the substrate surface, without any intervening adhesive, and encapsulates the LEDs and the traces, bond pads, or land pads. The molded material can be a thermoplastic material or a thermoset material. The substrate with the LEDs and the traces, bond pads, or land pads can be inserted into a mold, and either molten thermoplastic material or thermoset material liquid precursors can then be injected into the mold.

Objects and advantages pertaining to light-emitting apparatus may become apparent upon referring to the example embodiments illustrated in the drawings and disclosed in the following written description or appended claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIGS. 1 through 6 are schematic cross-sectional views illustrating an example sequence of steps for making an inventive light-emitting apparatus.

FIG. 7 is a schematic plan view of an inventive light-emitting apparatus.

The embodiments depicted are shown only schematically; all features may not be shown in full detail or in proper proportion; for clarity certain features or structures may be exaggerated or diminished relative to others or omitted entirely; the drawings should not be regarded as being to scale unless explicitly indicated as being to scale. The embodiments shown are only examples and should not be construed as limiting the scope of the present disclosure or appended claims.

### DETAILED DESCRIPTION

The following detailed description should be read with reference to the drawings, in which identical reference numbers refer to like elements throughout the different figures. The drawings, which are not necessarily to scale, depict selective examples and are not intended to limit the scope of the inventive subject matter. The detailed description illustrates by way of example, not by way of limitation, the principles of the inventive subject matter.

The LED array described above must be joined with an eyepiece of the OHMD (e.g., visor, goggles, glasses, or other eyewear). Inventive methods and apparatus are disclosed wherein the LEDs of the array are attached to a transparent backplane, and a transparent material is molded directly onto the backplane, without intervening adhesive, to form the eyepiece of the OHMD with the integrated LED array encapsulated by the molded material.

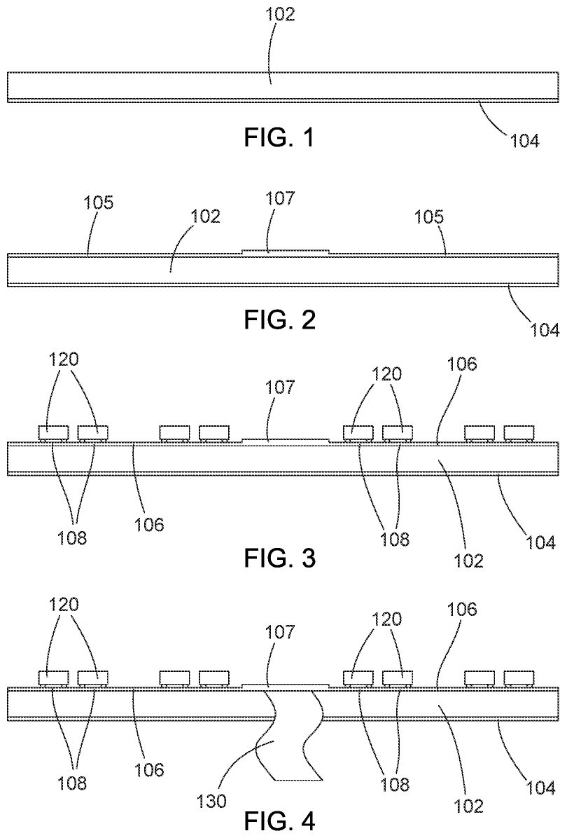

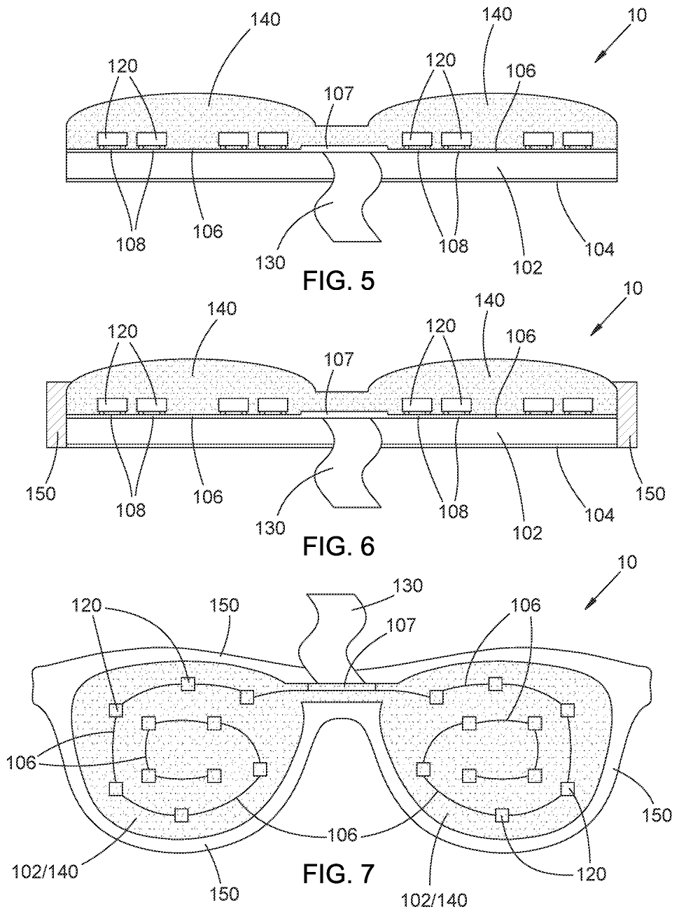

FIGS. 1 through 6 are schematic cross-sectional views illustrating an example inventive method for making a light-emitting apparatus 10 (i.e., the OHMD eyepiece with integrated LED array); FIG. 7 is a schematic plan view of the finished light-emitting apparatus 10. A transparent substrate 102 is shown in FIG. 1 and has opposite first and second surfaces. In some examples the substrate 102 can be rigid; in other examples the substrate 102 can be flexible. In some examples an anti-reflection coating 104 of any suitable type or arrangement can be included of the second surface of the substrate 102; in some other examples such an anti-reflection coating can be omitted. The substrate 102 can include any one or more suitably transparent materials, e.g., glass, silica, or clear polyimide. The substrate material must remain intact and stable when subjected to molding temperatures during subsequent molding of material to form the eyepiece (described below).

A thin layer 105 (e.g., 0.5 μm to 25 μm thickness) of electrically conductive material is formed, grown, or deposited on the first surface of the substrate 102 (FIG. 2). The conductive layer 105 can include one or more metals or metal alloys (e.g., Cu—Ni—Au, Cu, Al, or Ag) or one or more transparent conductive oxides (TCOs, e.g., indium tin oxide (ITO) or indium zinc oxide (IZO)). The conductive layer 105 (e.g., a single layer, or a stack of multiple sublayers) is patterned to form individual LED bond pads 108, traces 106 that connect the LEDs 120 in the array into a desired configuration, and land pads 107 (if desired for connecting an external electrical circuit, such as a flexible printed circuit (FPC)). The traces 106 and bond pads 108 are not distinguishable in the cross-sectional view of FIG. 2. The traces 106, bond pads 108, or land pads 107 can be formed using any one or more suitable spatially selective material processing techniques, e.g., standard photolithographic and wet chemical etching techniques. The thin conductive layer 105 can in some instances facilitate formation of narrow trace widths as well as closely spaced LED bond pads needed for attachment of mini- and micro-LEDs, especially in the case where the traces 106 and bond pads 108 are formed via isotropic, wet chemical etching.

The transparent substrate 102 together with the electrically conductive traces 106, bond pads 108, and land pads 107 (if present) can be referred to as the transparent backplane. In some examples the electrically conductive layer 105 can be transparent to visible light; in some examples the traces 106, bond pads 108, or land pads 107 can be small (e.g., at least one transverse dimension less than, e.g., 200 μm) and sparse (e.g., a fill factor less than 25%). In either case, the transparency or small size and low fill factor (or both) enable visual observation of a scene through the substrate along a sightline that passes through an area of the substrate 102 occupied by some or all of the traces 106, bond pads 108, or land pads 107.

The LEDs 120 are attached and electrically connected to corresponding bond pads 108 on the transparent backplane (FIG. 3). In some examples the LEDs 120 comprise one or more III-V semiconductor materials. The LEDs 120 are sufficiently small (e.g., less than 200 μm wide) and sufficiently sparse (e.g., fill factor less than 25%, often less than 5%) so as to enable visual observation of the scene along the sightline. The LEDs 120 can be attached to the corresponding bond pads 108 using any suitable electrically conductive die attach material, e.g., an anisotropic conductive adhesive (ACA) or solder paste with ultra-fine solder powder size. The die attach material must remain intact and stable when subjected to molding temperatures during subsequent molding of material to form the eyepiece (described below). The assembly of LEDs 120 on the transparent backplane is heated to cure the ACA or to reflow the solder paste, forming robust attachments. Infrared-emitting LEDs 120 (e.g., with an emission wavelength in the range of about 750 nm to about 1400 nm) can be suitably employed for eye tracking, because those wavelengths are practically invisible to the human eye and so would not disturb the user's experience. LEDs 120 emitting at about 850 nm can be advantageously employed due to higher quantum efficiency of common image sensors at this wavelength. In examples including one or more infrared-emitting LEDs, one or both of the substrate 102 or the molded material 140 should be transparent to the infrared light emitted by the infrared-emitting LEDs. Instead of, or in addition to, infrared-emitting LEDs 120, visible-emitting LEDs 120 (e.g., with an emission wavelength in the range of about 375 nm to about 750 nm) can be employed, e.g., for indicator lighting or overlaid information display in an OHMD display, or for decorative automotive signalling).

If needed or desired, the transparent backplane can be connected to an external electrical circuit (such as the FPC 130) at the land pad 107 (FIG. 4). The electrical circuit can be structured and connected to deliver electrical signals to the one or more LEDs 120 via the one or more land pads 107, traces 106, and bond pads 108. Any suitable material can be employed for the attachment, e.g., ACA or solder. Adhesive curing or solder reflow for attaching the circuit to the land pad 107 can be performed concurrently with attachment of the LEDs 120 to the bond pads 108, or can be performed as a separate step.

Transparent material 140 is molded directly onto at least a portion of the first surface of the substrate 102, without any intervening adhesive, so as to encapsulate some or all of the one or more LEDs 120 and some or all of the one or more traces 106, bond pads 108, or land pads 107. In some examples the molded material 140 can be formed over the LEDs 120, e.g., by insert injection molding in the case of a thermoplastic material 140, or by transfer or compression molding in case of a thermoset material 140. For an insert injection molding process, the preassembled transparent backplane with LEDs 120 is first placed by hand or automation onto the lower half of the mold. The upper half of the mold, which is preformed into the desired shape of the eyepiece surface, clamps down onto the lower half. Solid pellets of the chosen eyepiece material are melted and injected into the mold. In some examples the eyepiece material can exhibit high optical transparency, low haze, low birefringence, high impact and chemical resistance, low cost, and compatibility with injection molding. Some examples of suitable material can include, e.g., polycarbonates, polymethyl methacrylate (PMMA), polystyrenes, cyclic olefin polymers (COP), cyclic olefin copolymers (COC), or polyesters. The molten material fills the mold and encapsulates—partially or fully—the LEDs 120 array, the traces 106, the bond pads 108, and the land pads 107. As the thermoplastic 140 cools, it solidifies and assumes the desired shape. The mold is then opened and the piece removed or ejected from the mold. Any plastic runner at the molding gate can be mechanically separated from the finished light-emitting apparatus 10 (i.e., the eyepiece with integrated array of LEDs 120). If a thermoset material is employed, liquid precursors are injected into the mold, and the thermoset material is cured to solidify and assume the desired shape. The finished light-emitting apparatus 10 lacks any adhesive bonding the molded material 140 to the substrate 102, to the electrically conductive layer 105 (i.e., traces 106, bond pads 108, or land pads 107), or to the one or more LEDs 120.

In some examples, second molding step can be performed using a second molded material. The second material can be molded directly onto at least a portion of the substrate to form a frame 150 around at least the area of the substrate 102 through which the sightline passes (FIGS. 6 and 7). The second molded material can be transparent, translucent, or opaque, as needed or desired.

The disclosed inventive apparatus and methods can in some instances offer one or more advantages. As noted above, direct infrared illumination obviates the need for additional optical components to steer out-of-field infrared illumination to the user's eyes, which can reduce the overall system cost and also achieve a more consistent irradiance pattern. The one or more molding processes employed can ensure precise alignment and rigid mating of parts without the need of an intermediate adhesive layer or fastener, reducing assembly complexity and part cost. A relatively greater range of eyepiece shapes and designs can be formed with an integrated LED array. Unlike vacuum-lamination-based techniques wherein the mating surfaces must be nearly flat, molding can accommodate 3D structures on the mating side of the eyepiece. Molding of the eyepiece onto the LED array of the transparent backplane can achieve an improved cosmetic appearance, e.g., high optical transparency, reduced or eliminated light reflections from a refractive index mismatched adhesion layer, or low bubble and particle count.

In some examples the transparent backplane can include a pre-attached flexible printed circuit (FPC) 130 for purposes of forming an electrical connection between the integrated array of LEDs 120 and OHMD electronics. In some examples the molded material 140 can encapsulate the FPC connection to the backplane, improving mechanical support and robustness. Such an arrangement can also enable use of a single-sided backplane, with no need to drill holes into the substrate 102 for routing to back-side FPC land pads. A single-sided backplane can also facilitate deposition on the anti-reflection coating 104 on the second surface of the substrate 102.

In addition to the preceding, the following example embodiments fall within the scope of the present disclosure or appended claims. Any given Example below that refers to multiple preceding Examples shall be understood to refer to only those preceding Examples with which the given Example is not inconsistent, and to exclude implicitly those preceding Examples with which the given Example is inconsistent.
Example 1. A light-emitting apparatus comprising: (a) a substrate that is transparent to visible light, the substrate having opposite first and second surfaces; (b) an electrically conductive layer on the first surface of the substrate, the electrically conductive layer being patterned to form one or more electrically conductive traces, bond pads, or land pads, wherein (i) the electrically conductive layer is transparent to visible light, or (ii) the one or more traces, bond pads, or land pads are sufficiently small and sufficiently sparse, so as to enable visual observation of a scene through the substrate along a sightline that passes through an area of the substrate occupied by some or all of the one or more traces, bond pads, or land pads; (c) a set of one or more light-emitting diodes (LEDs) attached and electrically connected to one or more corresponding bond pads among the one or more bond pads, the LEDs being sufficiently small and sparse so as to enable visual observation of the scene along the sightline; and (d) a molded material molded directly onto at least a portion of the first surface of the substrate and encapsulating some or all of the one or more LEDs and some or all of the one or more traces, bond pads, or land pads, the molded material being transparent to visible light.
Example 2. The light-emitting apparatus of Example 1, the apparatus lacking any adhesive bonding the molded material to the substrate, to the electrically conductive layer, or to the one or more LEDs.
Example 3. The light-emitting apparatus of any one of Examples 1 or 2 further comprising an anti-reflection coating on at least a portion of the second surface of the substrate through which the sightline passes.
Example 4. The light-emitting apparatus of any one of Examples 1 through 3 further comprising an electrical circuit attached and electrically connected to the one or more land pads, the electrical circuit being structured and connected to deliver electrical signals to the one or more LEDs via the one or more land pads, traces, and bond pads.
Example 5. The light-emitting apparatus of any one of Examples 1 through 4 wherein the molded material includes (i) one or more thermoplastic materials or (ii) one or more thermoset materials.
Example 6. The light-emitting apparatus of any one of Examples 1 through 5 wherein: (i) the substrate comprises one or more of glass, silica, or clear polyimide; (ii) the electrically conductive layer comprises one or more metals or metal alloys or one or more transparent conductive oxides; (iii) the one or more LEDs comprise one or more III-V semiconductor materials; or (iv) the molded material comprises one or more polycarbonates, polymethyl methacrylate, polystyrenes, cyclic olefin polymers, cyclic olefin copolymers, or polyesters.
Example 7. The light-emitting apparatus of any one of Examples 1 through 6 further comprising a second molded material molded directly onto at least a portion of the substrate to form a frame around at least the area of the substrate through which the sightline passes.
Example 8. The light-emitting apparatus of any one of Examples 1 through 7 wherein the one or more LEDs include one or more infrared-emitting LEDs arranged to emit infrared light directed toward one or both eyes of a user with the substrate positioned so that the user's sightline passes through at least a portion of the substrate occupied by some or all of the one or more traces, bond pads, or land pads and some or all of the LEDs of the user, the light-emitting apparatus further comprising one or more infrared detectors arranged and connected so as to detect infrared light emitted by the one or more LEDs and scattered or reflected by one or both eyes of the user.
Example 9. The light-emitting apparatus of any one of Examples 1 through 8 wherein the one or more LEDs include one or more visible-emitting LEDs arranged and connected so as to display alphanumeric, symbolic, or graphic information in the sightline.
Example 10. An optical head-mounted display (OHMD) incorporating the light-emitting apparatus of any one of Examples 1 through 9, the OHMD being arranged so that, while the OHMD is worn by a user, the user's sightline passes through at least a portion of the substrate occupied by some or all of the one or more traces, bond pads, or land pads and some or all of the LEDs.
Example 11. A method for making a light-emitting apparatus comprising: (A) depositing an electrically conductive layer on a first surface of a substrate, the substrate having opposite first and second surfaces and being transparent to visible light; (B) patterning the electrically conductive layer to form one or more electrically conductive traces, bond pads, or land pads, wherein (i) the electrically conductive layer is transparent to visible light, or (ii) the one or more traces, bond pads, or land pads are sufficiently small and sufficiently sparse, so as to enable visual observation of a scene through the substrate along a sightline that passes through an area of the substrate occupied by some or all of the one or more traces, bond pads, or land pads; (C) attaching and electrically connecting a set of one or more light-emitting diodes (LEDs) to one or more corresponding bond pads among the one or more bond pads, the LEDs being sufficiently small and sparse so as to enable visual observation of the scene along the sightline; and (D) molding material directly onto at least a portion of the first surface of the substrate, without any intervening adhesive, so as to encapsulate some or all of the one or more LEDs and some or all of the one or more traces, bond pads, or land pads, the molded material being transparent to visible light.
Example 12. The method of Example 11 further comprising forming an anti-reflection coating on at least a portion of the second surface of the substrate through which the sightline passes.
Example 13. The method of any one of Examples 11 or 12 further comprising attaching and electrically connecting an electrical circuit to the one or more land pads, the electrical circuit being structured and connected to deliver electrical signals to the one or more LEDs via the one or more land pads, traces, and bond pads.
Example 14. The method of any one of Examples 11 through 13 wherein the molding of part (D) comprises: (i) inserting into a first part of a mold the substrate with the one or more traces, bond pads, or land pads and the one or more LEDs thereon; (ii) assembling one or more additional parts of the mold with the first part of the mold to complete the mold; (iii) injecting molten thermoplastic material into the completed mold; (iv) allowing the injected thermoplastic material to cool and solidify; and (v) disassembling the mold and ejecting the light-emitting apparatus from the mold.
Example 15. The method of any one of Examples 11 through 13 wherein the molding of part (D) comprises: (i) inserting into a first part of a mold the substrate with the one or more traces, bond pads, or land pads and the one or more LEDs thereon; (ii) assembling one or more additional parts of the mold with the first part of the mold to complete the mold; (iii) injecting thermoset material liquid precursors into the completed mold; (iv) allowing the injected thermoset material to cure and solidify; and (v) disassembling the mold and removing the light-emitting apparatus from the mold.
Example 16. The method of any one of Examples 11 through 15 wherein: (i) the substrate comprises one or more of glass, silica, or clear polyimide; (ii) the electrically conductive layer comprises one or more metals or metal alloys or one or more transparent conductive oxides; (iii) the one or more LEDs comprise one or more III-V semiconductor materials; or (iv) the molded material comprises one or more polycarbonates, polymethyl methacrylate, polystyrenes, cyclic olefin polymers, cyclic olefin copolymers, or polyesters.
Example 17. The method of any one of Examples 11 through 16 further comprising molding a second material directly onto at least a portion of the substrate to form a frame around at least the area of the substrate through which the sightline passes.
Example 18. The method of any one of Examples 11 through 17 wherein the one or more LEDs include one or more infrared-emitting LEDs arranged to emit infrared light directed toward one or both eyes of a user with the substrate positioned so that the user's sightline passes through at least a portion of the substrate occupied by some or all of the one or more traces, bond pads, or land pads and some or all of the LEDs of the user, the light-emitting apparatus further comprising one or more infrared detectors arranged and connected so as to detect infrared light emitted by the one or more LEDs and scattered or reflected by one or both eyes of the user.
Example 19. The method of any one of Examples 11 through 18 wherein the one or more LEDs include one or more visible-emitting LEDs arranged and connected so as to display alphanumeric, symbolic, or graphic information in the sightline.
Example 20. The method of any one of Examples 11 through 19 further comprising, after parts (A) through (D), incorporating the substrate into an optical head-mounted display (OHMD) so as to arrange the OHMD so that, while the OHMD is worn by a user, the user's sightline passes through at least a portion of the substrate occupied by some or all of the one or more traces, bond pads, or land pads and some or all of the LEDs.

This disclosure is illustrative and not limiting. Further modifications will be apparent to one skilled in the art in light of this disclosure and are intended to fall within the scope of the present disclosure or appended claims. It is intended that equivalents of the disclosed example embodiments and methods, or modifications thereof, shall fall within the scope of the present disclosure or appended claims.

In the foregoing Detailed Description, various features may be grouped together in several example embodiments for the purpose of streamlining the disclosure. This method of disclosure is not to be interpreted as reflecting an intention that any claimed embodiment requires more features than are expressly recited in the corresponding claim. Rather, as the appended claims reflect, inventive subject matter may lie in less than all features of a single disclosed example embodiment. Therefore, the present disclosure shall be construed as implicitly disclosing any embodiment having any suitable subset of one or more features—which features are shown, described, or claimed in the present application—including those subsets that may not be explicitly disclosed herein. A “suitable” subset of features includes only features that are neither incompatible nor mutually exclusive with respect to any other feature of that subset. Accordingly, the appended claims are hereby incorporated in their entirety into the Detailed Description, with each claim standing on its own as a separate disclosed embodiment. In addition, each of the appended dependent claims shall be interpreted, only for purposes of disclosure by said incorporation of the claims into the Detailed Description, as if written in multiple dependent form and dependent upon all preceding claims with which it is not inconsistent. It should be further noted that the cumulative scope of the appended claims can, but does not necessarily, encompass the whole of the subject matter disclosed in the present application.

The following interpretations shall apply for purposes of the present disclosure and appended claims. The words “comprising,” “including,” “having,” and variants thereof, wherever they appear, shall be construed as open ended terminology, with the same meaning as if a phrase such as “at least” were appended after each instance thereof, unless explicitly stated otherwise. The article “a” shall be interpreted as “one or more” unless “only one,” “a single,” or other similar limitation is stated explicitly or is implicit in the particular context; similarly, the article “the” shall be interpreted as “one or more of the” unless “only one of the,” “a single one of the,” or other similar limitation is stated explicitly or is implicit in the particular context. The conjunction “or” is to be construed inclusively unless: (i) it is explicitly stated otherwise, e.g., by use of “either . . . or,” “only one of,” or similar language; or (ii) two or more of the listed alternatives are understood or disclosed (implicitly or explicitly) to be incompatible or mutually exclusive within the particular context. In that latter case, “or” would be understood to encompass only those combinations involving non-mutually-exclusive alternatives. In one example, each of “a dog or a cat,” “one or more of a dog or a cat,” and “one or more dogs or cats” would be interpreted as one or more dogs without any cats, or one or more cats without any dogs, or one or more of each.

For purposes of the present disclosure or appended claims, when a numerical quantity is recited (with or without terms such as “about,” “about equal to,” “substantially equal to,” “greater than about,” “less than about,” and so forth), standard conventions pertaining to measurement precision, rounding error, and significant digits shall apply, unless a differing interpretation is explicitly set forth, or if a differing interpretation is implicit or inherent (e.g., some small integer quantities). For null quantities described by phrases such as “equal to zero,” “absent,” “eliminated,” “negligible,” “prevented,” and so forth (with or without terms such as “about,” “substantially,” and so forth), each such phrase shall denote the case wherein the quantity in question has been reduced or diminished to such an extent that, for practical purposes in the context of the intended operation or use of the disclosed or claimed apparatus or method, the overall behavior or performance of the apparatus or method does not differ from that which would have occurred had the null quantity in fact been completely removed, exactly equal to zero, or otherwise exactly nulled. Terms such as “parallel,” “perpendicular,” “orthogonal,” “flush,” “aligned,” and so forth shall be similarly interpreted (with or without terms such as “about,” “substantially,” and so forth).

For purposes of the present disclosure and appended claims, any labelling of elements, steps, limitations, or other portions of an embodiment, example, or claim (e.g., first, second, third, etc., (a), (b), (c), etc., or (i), (ii), (iii), etc.) is only for purposes of clarity, and shall not be construed as implying any sort of ordering or precedence of the portions so labelled. If any such ordering or precedence is intended, it will be explicitly recited in the embodiment, example, or claim or, in some instances, it will be implicit or inherent based on the specific content of the embodiment, example, or claim. In the appended claims, if the provisions of 35 USC § 112(f) are desired to be invoked in an apparatus claim, then the word “means” will appear in that apparatus claim. If those provisions are desired to be invoked in a method claim, the words “a step for” will appear in that method claim. Conversely, if the words “means” or “a step for” do not appear in a claim, then the provisions of 35 USC § 112(f) are not intended to be invoked for that claim.

If any one or more disclosures are incorporated herein by reference and such incorporated disclosures conflict in part or whole with, or differ in scope from, the present disclosure, then to the extent of conflict, broader disclosure, or broader definition of terms, the present disclosure controls. If such incorporated disclosures conflict in part or whole with one another, then to the extent of conflict, the later-dated disclosure controls.

The Abstract is provided as required as an aid to those searching for specific subject matter within the patent literature. However, the Abstract is not intended to imply that any elements, features, or limitations recited therein are necessarily encompassed by any particular claim. The scope of subject matter encompassed by each claim shall be determined by the recitation of only that claim.

What is claimed is:

1. A light-emitting apparatus comprising:
(a) a substrate that is transparent to visible light, the substrate having opposite first and second surfaces;
(b) an electrically conductive layer on the first surface of the substrate, the electrically conductive layer being patterned to form one or more electrically conductive traces, bond pads, or land pads, wherein (i) the electrically conductive layer is transparent to visible light, or (ii) the one or more traces, bond pads, or land pads are sufficiently small and sufficiently sparse, so as to enable visual observation of a scene through the substrate along a sightline that passes through an area of the substrate occupied by some or all of the one or more traces, bond pads, or land pads;
(c) a set of one or more light-emitting diodes (LEDs) attached and electrically connected to one or more corresponding bond pads among the one or more bond pads, the LEDs being sufficiently small and sparse so as to enable visual observation of the scene along the sightline; and
(d) a molded material molded directly onto at least a portion of the first surface of the substrate and encapsulating some or all of the one or more LEDs and some or all of the one or more traces, bond pads, or land pads, the molded material being transparent to visible light.

2. The light-emitting apparatus of claim 1, the apparatus lacking any adhesive bonding the molded material to the substrate, to the electrically conductive layer, or to the one or more LEDs.

3. The light-emitting apparatus of claim 1 further comprising an anti-reflection coating on at least a portion of the second surface of the substrate through which the sightline passes.

4. The light-emitting apparatus of claim 1 further comprising an electrical circuit attached and electrically connected to the one or more land pads, the electrical circuit being structured and connected to deliver electrical signals to the one or more LEDs via the one or more land pads, traces, and bond pads.

5. The light-emitting apparatus of claim 1 wherein the molded material includes (i) one or more thermoplastic materials or (ii) one or more thermoset materials.

6. The light-emitting apparatus of claim 1 wherein: (i) the substrate comprises one or more of glass, silica, or clear polyimide; (ii) the electrically conductive layer comprises one or more metals or metal alloys or one or more transparent conductive oxides; (iii) the one or more LEDs comprise one or more III-V semiconductor materials; or (iv) the molded material comprises one or more polycarbonates, polymethyl methacrylate, polystyrenes, cyclic olefin polymers, cyclic olefin copolymers, or polyesters.

7. The light-emitting apparatus of claim 1 further comprising a second molded material molded directly onto at least a portion of the substrate to form a frame around at least the area of the substrate through which the sightline passes.

8. The light-emitting apparatus of claim 1 wherein the one or more LEDs include one or more infrared-emitting LEDs arranged to emit infrared light directed toward one or both eyes of a user with the substrate positioned so that the user's sightline passes through at least a portion of the substrate occupied by some or all of the one or more traces, bond pads, or land pads and some or all of the LEDs of the user, the light-emitting apparatus further comprising one or more infrared detectors arranged and connected so as to detect infrared light emitted by the one or more LEDs and scattered or reflected by one or both eyes of the user.

9. The light-emitting apparatus of claim 1 wherein the one or more LEDs include one or more visible-emitting LEDs arranged and connected so as to display alphanumeric, symbolic, or graphic information in the sightline.

10. An optical head-mounted display (OHMD) incorporating the light-emitting apparatus of claim 1, the OHMD being arranged so that, while the OHMD is worn by a user, the user's sightline passes through at least a portion of the substrate occupied by some or all of the one or more traces, bond pads, or land pads and some or all of the LEDs.

11. A method for making a light-emitting apparatus comprising:
(A) depositing an electrically conductive layer on a first surface of a substrate, the substrate having opposite first and second surfaces and being transparent to visible light;
(B) patterning the electrically conductive layer to form one or more electrically conductive traces, bond pads, or land pads, wherein (i) the electrically conductive layer is transparent to visible light, or (ii) the one or more traces, bond pads, or land pads are sufficiently small and sufficiently sparse, so as to enable visual observation of a scene through the substrate along a sightline that passes through an area of the substrate occupied by some or all of the one or more traces, bond pads, or land pads;
(C) attaching and electrically connecting a set of one or more light-emitting diodes (LEDs) to one or more corresponding bond pads among the one or more bond pads, the LEDs being sufficiently small and sparse so as to enable visual observation of the scene along the sightline; and
(D) molding material directly onto at least a portion of the first surface of the substrate, without any intervening adhesive, so as to encapsulate some or all of the one or more LEDs and some or all of the one or more traces, bond pads, or land pads, the molded material being transparent to visible light.

12. The method of claim 11 further comprising forming an anti-reflection coating on at least a portion of the second surface of the substrate through which the sightline passes.

13. The method of claim 11 further comprising attaching and electrically connecting an electrical circuit to the one or more land pads, the electrical circuit being structured and connected to deliver electrical signals to the one or more LEDs via the one or more land pads, traces, and bond pads.

14. The method of claim 11 wherein the molding of part (D) comprises:
(i) inserting into a first part of a mold the substrate with the one or more traces, bond pads, or land pads and the one or more LEDs thereon; (ii) assembling one or more additional parts of the mold with the first part of the mold to complete the mold; (iii) injecting molten thermoplastic material into the completed mold; (iv) allowing the injected thermoplastic material to cool and solidify; and (v) disassembling the mold and ejecting the light-emitting apparatus from the mold.

15. The method of claim 11 wherein the molding of part (D) comprises: (i) inserting into a first part of a mold the substrate with the one or more traces, bond pads, or land pads and the one or more LEDs thereon; (ii) assembling one or more additional parts of the mold with the first part of the mold to complete the mold; (iii) injecting thermoset material liquid precursors into the completed mold; (iv) allowing the injected thermoset material to cure and solidify; and (v) disassembling the mold and removing the light-emitting apparatus from the mold.

16. The method of claim 11 wherein: (i) the substrate comprises one or more of glass, silica, or clear polyimide; (ii) the electrically conductive layer comprises one or more metals or metal alloys or one or more transparent conductive oxides; (iii) the one or more LEDs comprise one or more III-V semiconductor materials; or (iv) the molded material comprises one or more polycarbonates, polymethyl methacrylate, polystyrenes, cyclic olefin polymers, cyclic olefin copolymers, or polyesters.

17. The method of claim 11 further comprising molding a second material directly onto at least a portion of the substrate to form a frame around at least the area of the substrate through which the sightline passes.

18. The method of claim 11 wherein the one or more LEDs include one or more infrared-emitting LEDs arranged to emit infrared light directed toward one or both eyes of a user with the substrate positioned so that the user's sightline passes through at least a portion of the substrate occupied by some or all of the one or more traces, bond pads, or land pads and some or all of the LEDs of the user, the light-emitting apparatus further comprising one or more infrared detectors arranged and connected so as to detect infrared light emitted by the one or more LEDs and scattered or reflected by one or both eyes of the user.

19. The method of claim 11 wherein the one or more LEDs include one or more visible-emitting LEDs arranged and connected so as to display alphanumeric, symbolic, or graphic information in the sightline.

20. The method of claims 11 further comprising, after parts (A) through (D), incorporating the substrate into an optical head-mounted display (OHMD) so as to arrange the OHMD so that, while the OHMD is worn by a user, the user's sightline passes through at least a portion of the substrate occupied by some or all of the one or more traces, bond pads, or land pads and some or all of the LEDs.
